(19) United States
(12) Patent Application Publication
(10) Pub. No.: US 2025/0291671 A1
(43) Pub. Date: Sep. 18, 2025

(54) APPARATUSES AND METHODS FOR ADJUSTING REFRESH RATES ON MEMORY DEVICES OF A MODULE

(71) Applicant: Micron Technology, Inc., Boise, ID (US)

(72) Inventors: Sujeet Ayyapureddi, Boise, ID (US); Wesley W. Borie, Boise, ID (US); Matthew D. Jenkinson, Boise, ID (US); Dennis G. Montierth, Meridian, ID (US); Nathan D. Good, Boise, ID (US); Shawn M. Hilde, Boise, ID (US); Garth N. Grubb, Boise, ID (US)

(73) Assignee: Micron Technology, Inc., Boise, ID (US)

(21) Appl. No.: 19/049,834

(22) Filed: Feb. 10, 2025

Related U.S. Application Data
(60) Provisional application No. 63/564,416, filed on Mar. 12, 2024.

(51) Int. Cl. G06F 11/07

(52) U.S. Cl. CPC G06F 11/0793; G06F 11/0727; G06F 11/079

(57) ABSTRACT

A memory module includes a number of memory devices which receive refresh commands. Each memory device may adjust its refresh rate based on error information on the device. For example, each device may perform error correct and scrub (ECS) operations and track ECS information based on a count of corrected errors. That ECS information may be used to determine if the refresh rate should be adjusted up or down. For example, if the ECS information indicates an increase in errors, the refresh rate may be adjusted upwards.

### CROSS-REFERENCE TO RELATED APPLICATIONS

This application claims the filing benefit of U.S. Provisional Application No. 63/564,416, filed Mar. 12, 2024. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed. Multiple memory devices may be packaged together in a module, which is operated by a controller.

Information may decay over time in the memory cells. In order to preserve the integrity of the stored information, the memory cells may be refreshed. However, refreshing memory cells may take up power, as well as time which the memory could have spent on other operations. While reducing refresh operations may reduce power consumption, downtime, or both, it may also increase the errors in information stored in the memory array. There may be a need to balance these factors.

### BRIEF DESCRIPTION OF THE DRAWINGS

FIG. 1 is a block diagram of a memory system according to some embodiments of the present disclosure.

FIG. 2 is a block diagram of a semiconductor device according to some embodiments of the disclosure.

FIG. 3 is a block diagram of a refresh control circuit according to some embodiments of the present disclosure.

FIG. 4 is a block diagram of a refresh rate adjustment circuit according to some embodiments of the present disclosure.

FIG. 5 is a flow chart of a method of adjusting refresh rates based on ECS information according to some embodiments of the present disclosure.

FIG. 6 is a flow chart of a method of adjusting refresh rates based on ECS information at the end of an ECS cycle according to some embodiments of the present disclosure.

FIG. 7 is a flow chart of a method of continuously monitoring ECS information and adjusting the refresh rate based on that monitoring according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems (e.g., memory systems), apparatuses (e.g., memory devices, circuits, semiconductor devices), methods, or combinations thereof, reference is made to the accompanying drawings which form a part hereof, and which are shown by way of illustration specific embodiments in which the described systems, apparatuses, and methods may be practiced. These embodiments are described in sufficient detail to enable those skilled in the art to practice presently disclosed systems, apparatuses, and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory devices store information in memory arrays. The memory array includes memory cells, organized at the intersection of word lines (rows) and bit lines (columns). Each memory cell may store a bit of information. During an access operation, a row address may be used to specify a word line and a column address may be used to specify one or more bit lines. The information in the memory cells at the intersection of the specified word line and bit lines may be accessed. The information may generally be accessed in blocks of set size or ‘codewords’. For example, each row and column address may generally access a single codeword (along with its associated error correction bits). Memory devices may perform refresh operations to maintain the integrity of the information stored in the array. For example a memory may perform refresh operations on a row-by-row basis.

The memory devices may also have error correction capabilities. Each memory device may include an error correction code (ECC) circuit. During read operations, the ECC circuit can correct up to a certain number of bits which are in error. For example, the ECC circuit may perform single error correction (SEC) and be able to repair up to one bit in error in a codeword as part of a read operation. As well as correcting during read operations, the memory devices may perform error check and scrub (ECS) operations. In an example ECS operation, the memory may systematically check every stored codeword over the course of an ECS cycle on a word line-by-word line basis and correct any (correctable) errors detected by overwriting the stored bit with the corrected state. The memory may store ECS information that may include a count of how many codewords were found to contain an error, an address and that may also include a count of the row with the most codewords with an error, other metrics, or combinations thereof. The ECS information may act as a metric of the amount of errors on the device over the previous ECS cycle.

Memory devices may be packaged together onto a memory module. The memory module may include one or more memory devices used to store data, and in some versions one or more error correction memory devices. The optional error correction memory device(s) may store information used to correct errors when data is read out from the memory. The memory module may receive refresh commands (e.g., from a controller) and responsive to the refresh command, the memory devices perform refresh operations. The controller may provide memory commands based on a ‘worst case’ assumption about the rate at which information decays in the memory module, however those assumptions may not be valid for each memory device. Accordingly, some memory devices on the module may over refresh (e.g., perform more refresh operations than are needed) or under refresh and lose information.

The present disclosure is drawn to apparatuses, systems, and methods for adjusting refresh rates on memory devices of a module. Each memory device on a module may adjust its refresh rate based on the ECS information stored on that memory device. For example, responsive to a refresh command, different memory devices may perform different numbers of refresh operations based on their adjusted rates. In this manner, even though the memory devices of the module may receive refresh commands in common, they may perform different rates of refresh operations. For example, each memory device on the module may check the ECS information of that device and increase the refresh rate if the ECS information indicates a rate of error above an upper threshold, decrease the refresh rate if the ECS information indicates a rate of error below a lower threshold, or maintain the refresh rate if the ECS information indicates a rate of error between the upper and lower thresholds. In some embodiments, the ECS information may be checked and the rate may be adjusted at certain time points (e.g., after an ECS cycle has completed). In some embodiments, the ECS information may be continuously monitored (e.g., checked throughout the ECS cycle).

In some example embodiments, a memory device includes a refresh adjustment circuit. When an ECS cycle completes, the refresh adjustment circuit receives updated ECS information (e.g., an error count) and compares the updated ECS information to previous ECS information (e.g., from a previous ECS cycle). After the comparison the updated ECS information may be stored as the previous ECS information. Based on that comparison the refresh rate may be adjusted up, down, or kept the same. For example, if the difference between the previous and current ECS information is too great (e.g., above an upper threshold) indicating that the amount of errors are increasing, the refresh rate may need to be increased, while if the amount of errors is decreasing (e.g., the below a lower threshold) then it may be possible to decrease the refresh rate.

In some embodiments, rather than wait for the end of an ECS cycle, the refresh rate adjustment circuit may perform more frequent checks. For example, the ECS information may be checked after ECS operations are performed on a bank, or after ECS operations are performed on a set number of word lines. In some embodiments with more frequent checks than the end of an ECS cycle (e.g., at the end of performing ECS operations on the entire array) there may be separate values of ECS information for the different sub-divisions. For example, if the refresh rate is adjusted after ECS operations are performed on a bank, then each bank may have its own separate ECS register to store its own separate ECS information.

In some embodiments, the ECS information may be continuously monitored for refresh rate adjustment. The ECS information may be monitored and used to generate an error rate. For example, the current ECS information may be used to determine a rate of errors over the last N word lines checked with ECS operations. If that error rate rises above a threshold, the device may increase its refresh rate. Since ECS cycles may be relatively long, this may allow more granularity in when the refresh rate is adjusted and may help to prevent situations where the memory has to issue an alert that an error rate was exceeded.

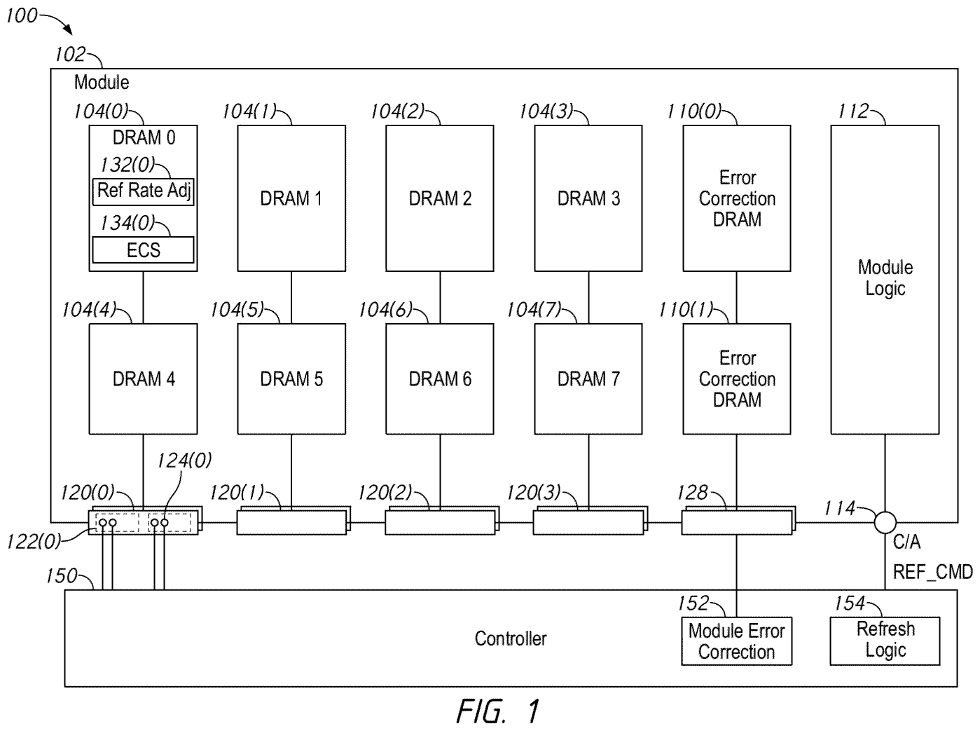

FIG. 1 is a block diagram of a memory system according to some embodiments of the present disclosure. The memory system 100 includes a memory module 102 and a controller 150. The controller 150 operates the memory module 102. The module includes one or more memory devices 104 and 110. The memory devices 104 may be used to store data and may generally be referred to as data memory devices 104, while the memory devices 110 are used to correct errors in data read from the data memory devices 104. The memory devices 110 may be referred to as error correction memory devices 110. A module logic circuit 112 receives signals such as commands and addresses over a command/address C/A bus from the controller 150 through a C/A terminal 114 and distributes those commands and addresses to the memory devices 104 and 110 over internal command and address buses (not shown). Data is communicated between the controller 150 and the module 102 along data buses which couple to data terminals (DQ) terminals 124 of the module 102. The data terminals 124 are organized into pseudo-channels 122 and channels 120. Each channel 120 is a set of data terminals 124 associated with a memory device 104. A similar set of channels 128 couple the error correction devices 110 to the controller 150.

FIG. 1 shows an example 10x2p2 or 10x4 memory module 102 that may be used to implement some embodiments of the present disclosure. In the 10x4 architecture, there are ten total memory devices 104 and 110. Eight data memory devices 104(0) to 104(7) and two error correction memory devices 110(0) and 110(1). Other memory architectures may be used in other example embodiments. For example there may be more or fewer data devices 104 and/or more or fewer error correction devices 110.

The data memory devices 104 are coupled to the controller through respective channels 120 and the error correction devices 110 are coupled through respective channels 128. Each channel 120(0) to 120(7) and 128(0) to 128(1) includes one or more pseudo-channels 122, which may be operated independently of each other. In this embodiment, each channel 120 or 128 includes two pseudo-channels 122, each of which includes two data terminals 124. Since the memory devices and channels may generally be similar to each other, only a single device 104(0) and its associate channel 120(0) are described in detail herein. Similarly, only internal components of a single data device 104(0) are shown and described. However, each of the data devices 104 (and/or error correction devices 110) may have similar components. Other numbers of pseudo-channels 122 per channel and other numbers of data terminals 124 per pseudo-channels may be used in other example embodiments.

In order to simplify the layout of the figure, an arrangement of two rows of four data devices 104 and one error correction device 110 each is shown, and their associated channels 120 are shown as stacked boxes. However the representation of FIG. 1 does not necessarily represent the layout of a physical device. For example, a single row of 8 data devices 104 and two error correction devices 110 may be used. Similarly, various buses and signal lines have been simplified down to a single line for clarity on the drawing, however, multiple physical signal lines may be represented by a single line in the drawing.

During an example write operation, the controller 150 provides a write command and addresses (e.g., a row address, column address, bank address, or combinations thereof as explained in more detail herein) over the C/A terminal 114 to the module 102. The module logic 112 distributes the command and address to the data memory devices 104(0) to 104(7) and ECC devices 110(0) and 110(1). The controller 150 also provides data to be written along the various DQ channels 120(0) to 120(7). Since the pseudo-channels 122 may be operated independently, we will consider a single pseudo-channel 122 and its two DQ terminals 124. Each data terminal receives a serial burst of bits, which together represent a codeword of data. For example, the memory device 104 may receive a burst of 16 serial bits along each of four DQ terminals. The received data is written to the memory array of the data devices 104.

As part of the write operation a module error correction circuit 152 of the controller may generate a set of module parity bits based on the data which is written. For example, the module parity bits may be based off of all of the data written to all of the data devices 104. For example, if each data device 104 receives 64 bits of data, then the module parity bits may be generated based off of the full set of 512 bits of data. The module parity bits may be written to the error correction devices 110 in a fashion analogous to the way the data is written to the data devices 104.

During an example read operation, the controller 150 provides a read command and addresses along the C/A terminal 114. The module logic 112 distributes these to the memory devices 104 to 110 and data is read out from the locations specified by the addresses in the data devices 104 and module parity is read out from the error correction devices 110.

The module error correction circuit 152 may perform error correction based on the amount of module parity bits which are read. For example, the module error correction circuit 152 may capable of ‘chipkill’ or correcting up to entire data from a data device 104. Other levels of module error correction may be used in other example embodiments.

During an example refresh operation (e.g., an auto-refresh operation), a refresh logic circuit 154 of the controller provides a refresh command REF_CMD to the module 102. The refresh command may be an all bank refresh command, a per-bank refresh command, or other type of refresh command. The module logic 112 distributes the refresh command to the devices 104 and 110. Responsive to the refresh command the devices 104-110 perform one or more refresh operations. Each of the devices 104 and 110 may include a respective refresh rate adjustment circuit 132 which determines a rate at which that device performs refresh operations responsive to the refresh command. For example, the refresh rate adjustment circuit 132 may determine a quantity of refresh operations which are performed responsive to each refresh command REF_CMD. For example, the quantity may determine what number of refresh operations are performed. In this manner, although the different devices 104 and 110 receive the refresh commands REF_CMD in common, they may perform refresh operations at different rates (e.g., different numbers of refresh operation per command).

Each device 104 and 110 includes a respective refresh rate adjustment circuit 132 and respective ECS information, for example stored in an ECS register 134. For clarity only the refresh rate adjustment circuit 132(0) and ECS register 134(0) of the device 104(0) are shown in FIG. 1. The refresh rate adjustment circuit 132(0) sets a refresh rate for the device 104(0) based in part on the ECS information in the ECS register 134(0). In some embodiments, if the ECS information indicates an increased number of errors (or rate of errors), the refresh rate adjustment circuit 132(0) may increase the rate at which refresh operations are performed on the device 104(0), while if the ECS information indicates a decreased number of errors (or rate of errors), the refresh rate adjustment circuit 132(0) may decrease the rate at which refresh operations are performed on the device 104(0). Since each of the devices 104 and 110 tracks device specific ECS information, the different devices 104 and 110 may have different refresh rates.

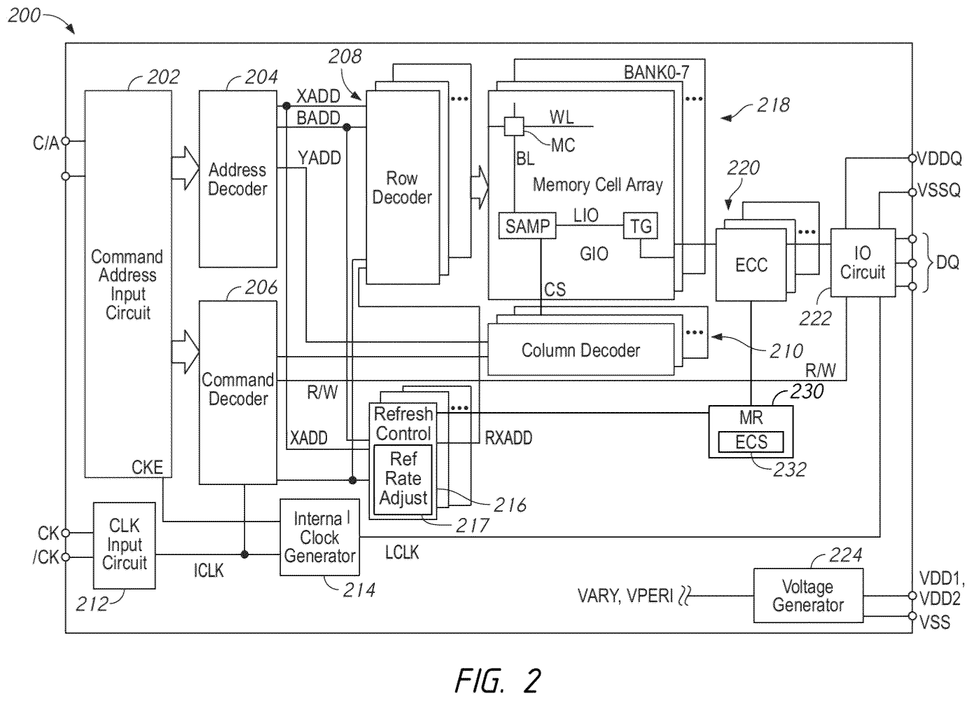

FIG. 2 is a block diagram of a semiconductor device according to some embodiments of the disclosure. The semiconductor device 200 may be a semiconductor memory device, such as a DRAM device integrated on a single semiconductor chip. For example, the device 100 may implement one of the devices 104 of the module 102 of FIG. 1 and/or one of the devices 110 of FIG. 1. For the sake of explanation, the memory device 200 will generally be described with respect to the operations of a data device, such as 104 of FIG. 1, however the error correction devices 110 of FIG. 1 may operate in an analogous fashion.

The semiconductor device 200 includes a memory array 218. The memory array 218 is shown as including a plurality of memory banks. In the embodiment of FIG. 2, the memory array 218 is shown as including eight memory banks BANK0-BANK7. More or fewer banks may be included in the memory array 218 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 208 and the selection of the bit lines BL is performed by a column decoder 210. In the embodiment of FIG. 2, the row decoder 208 includes a respective row decoder for each memory bank and the column decoder 210 includes a respective column decoder for each memory bank.

The bit lines BL are coupled to a respective sense amplifier (SAMP). Read data from the bit line BL is amplified by the sense amplifier SAMP, and transferred to an ECC circuit 220 over local data lines (LIO), transfer gate (TG), and global data lines (GIO). Conversely, write data outputted from the ECC circuit 220 is transferred to the sense amplifier SAMP over the complementary main data lines GIO, the transfer gate TG, and the complementary local data lines LIO, and written in the memory cell MC coupled to the bit line BL.

The semiconductor device 200 may employ a plurality of external terminals, such as solder pads, that include command and address (C/A) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may couple directly to the controller (e.g., 150 of FIG. 1) and/or may couple to various buses/connectors of the module (e.g., 102 of FIG. 1).

The clock terminals are supplied with external clocks CK and /CK that are provided to an input circuit 212. The external clocks may be complementary. The input circuit 212 generates an internal clock ICLK based on the CK and /CK clocks. The ICLK clock is provided to the command decoder 206 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output circuit 222, for example, to data receivers to time the receipt of write data. The input/output circuit 222 may include one or more interface connections, each of which may be couplable to one of the DQ pads (e.g., the solder pads which may act as external connections to the device 200).

The C/A terminals may be supplied with memory addresses. The memory addresses supplied to the C/A terminals are transferred, via a command/address input circuit 202, to an address decoder 204. The address decoder 204 receives the address and supplies a decoded row address XADD to the row decoder 208 and supplies a decoded column address YADD to the column decoder 210. The decoded row address XADD may be used to determine the word line to be activated. When the word line is activated, data in the memory cells along the active word line is coupled to the intersecting bit lines. The column decoder 210 may provide a column select signal CS based on the column address YADD. A value of the CS signal may be used to determine which sense amplifiers provide data to the LIO. The address decoder 204 may also supply a decoded bank address BADD. The bank address BADD may indicate the bank of the memory array 218 which is being accessed. For example, the bank address BADD may determine which row decoder 208 and which column decoder 210 are used as part of the access operation and in turn determine which bank is accessed.

The C/A terminals may be supplied with commands. Examples of commands include timing commands for controlling the timing of various operations, access commands for accessing the memory, such as read commands for performing read operations and write commands for performing write operations, refresh commands such as all-bank refresh and partial bank refresh, as well as other commands and operations. The access commands may be associated with one or more row address XADD, column address YADD, and bank address BADD to indicate the memory cell(s) to be accessed.

The commands may be provided as internal command signals to a command decoder 206 via the command/address input circuit 202. The command decoder 206 includes circuits to decode the internal command signals to generate various internal signals and commands for performing operations. For example, the command decoder 206 may provide signals which indicate if data is to be read, written, etc. The command decoder 206 may also provide one or more activations of a refresh signal REF responsive to a refresh command (e.g., REF_CMD of FIG. 1).

The device 200 may receive an access command which is a write command. When the write command is received, and a bank address, a row address and a column address are timely supplied with the write command, write data supplied to the data terminals DQ by the controller is provided along the data bus and written to memory cells in the memory array 218 corresponding to the row address and column address. The write command is received by the command decoder 206, which provides internal commands to perform the write operation. Write data is received by the IO circuit 222 and provided to an ECC circuit 220, which generates parity bits based on the write data. The row decoder 208 activates a word line based on the row address XADD, and the column decoder 210 couples bit lines selected by a column select signal CS (which is based on the column address YADD) to the LIO and GIO. The write data and parity is written to the memory cells at the intersection of the active word line and the selected bit lines.

The device 200 may receive an access command which is a read command. When a read command is received, and a bank address, a row address and a column address are timely supplied with the read command, read data and its associated parity is read from memory cells in the memory array 218 corresponding to the row address and column address in the bank specified by the bank address. The read command is received by the command decoder 206 and the command decoder 206 provides internal commands to activate the row indicated by the row address and couple the columns indicated by the column address through the LIO and GIO to the ECC circuit 220. Data and parity is read out to the ECC circuit 220, which corrects errors in the data based on the data and parity bits. The corrected data is provided to the IOC circuit 222, which provides the data to the DQ terminals.

The device 200 includes a mode register 230. The mode register includes one or more storage elements, such as latch circuits, organized in registers. The registers store information such as settings of the memory. A controller (e.g., 150 of FIG. 1) may perform a mode register read operation to retrieve information from a specified register or a mode register write operation to write information to a specified register. Some registers may be read only to prevent the controller from modifying them. Some registers may be updated based on conditions or operations of the memory. For example a refresh rate multiplier register may be set based on a measured temperature of the array 218.

The mode register 220 includes an error correction and scrub ECS register 232. The ECS register 232 stores information about a number of errors detected on the memory device 200. The memory device may perform an ECS operation by reading out information in the array 218 to the ECC circuit 220, determining if there is a correctable error, and then writing the corrected data back to the array 218. Over the course of an ECS cycle, the memory device 200 may work its way through all of the array 218. For example, the memory device 200 may perform an ECS cycle over the course of 24 hours. In this manner, over the course of an ECS cycle the memory device 200 may check all of the codewords of the array for correctable errors and correct them. The ECS operations may be performed over time as a background operation (e.g., when the memory device 200 is in an idle state).

The memory device 200 may update an ECS register 232 in the mode register 230 over the course of an ECS cycle. For example, the ECS register 232 may be an ECS count value, which tracks a number of errors which were detected during the previous ECS cycle. When the device performs an ECS operation, if an error is detected and corrected as part of the ECS operation, the ECS count value may be changed (e.g., incremented). At the end of an ECS cycle, the ECS count value may overwrite the previous ECS count value in the ECS register 242. Other ways of tracking ECS information may be used in addition to, or instead of the ECS count value. For example, in some embodiments, the ECS register 232 may store an ECS count value for each of the banks of the array 218. In some embodiments, the ECS register 232 may store information such as, such as the highest number of errors along a single word line. In some embodiments, as well as counts of errors, additional information, such as the address of the word line with the highest number of errors, may also be stored in the ECS register.

The device 200 includes refresh control circuits 216 each associated with a bank of the memory array 218. Each refresh control circuit 216 may determine when to perform a refresh operation on the associated bank. Responsive to the refresh signal REF, the refresh control circuit 216 performs one or more refresh operations. As part of a refresh operation, the refresh control circuit 216 provides a refresh address RXADD (along with one or more refresh signals, not shown in FIG. 1). The row decoder 208 performs a refresh operation on one or more word lines associated with RXADD. The refresh control circuit 216 may perform multiple types of refresh operation, which may determine how the address RXADD is generated, as well as other details such as how many word lines are associated with the address RXADD.

As part of a normal or sequential (or CBR) refresh operation, the refresh address RXADD may be generated based on a sequence of refresh addresses. For example, each refresh address RXADD may be based on a previous value of RXADD (e.g., RXADD(i+1)=RXADD(i)+1). As part of a targeted refresh operation, the refresh address RXADD may be generated based on an identified aggressor address. For example, the refresh control circuit 216 may identify an aggressor based on how many times that address has been accessed, and then generate refresh addresses which are associated with the victims of that aggressor. For example, the victims may be the word lines which are adjacent to the aggressor (e.g., RXADD=Aggressor+/−1). Other relationships between the aggressor and refresh addresses and other numbers of refresh addresses per aggressor may be used in other example embodiments.

The refresh control circuit 216 includes a refresh rate adjustment circuit 217. Based on the ECS information in the ECS register 242, the refresh rate adjustment circuit 217 may adjust a rate of refresh operations which the refresh control circuit 216 performs. For example, the refresh rate adjustment circuit 217 may change a quantity of refresh operations which the refresh control circuit 216 performs responsive to the refresh signal REF. The refresh rate adjustment circuit 217 uses the ECS information to determine whether or not the refresh rate should be adjusted, which direction to adjust the refresh rate, how much to adjust the refresh rate, or combinations thereof. In some embodiments, the ECS information may be compared to one or more thresholds. In some embodiments, the ECS information may be compared to previous ECS information. For example, the difference between the current ECS information and the previous ECS information may be compared to one or more thresholds.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

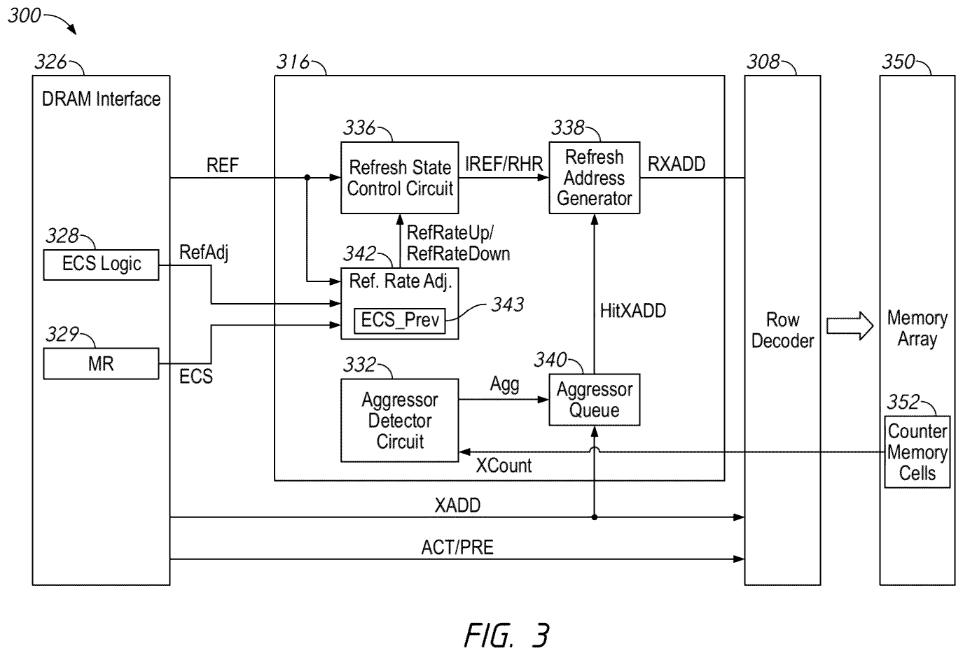

FIG. 3 is a block diagram of a refresh control circuit according to some embodiments of the present disclosure. The memory 300 may, in some embodiments, implement a portion of a memory device such as 104/110 of FIGS. 1 and/or 200 of FIG. 2. The memory 300 shows certain components and signals which are used in refresh operations. The memory 300 includes a refresh control circuit 316 which may, in some embodiments implement the refresh control circuit 216 of FIG. 2. Also shown in FIG. 3 is a row decoder 308 (e.g., 208 of FIG. 2), a memory array 350 (e.g., 218 of FIG. 2) and a DRAM interface 326, which represents other components of the memory, such as the command decoder (e.g., 206 of FIG. 2) and address decoder (e.g., 204 of FIG. 2). The DRAM interface 326 is shown as including a fuse array 328 (e.g., 240 of FIG. 2) and a mode register 329 (e.g., 230 of FIG. 2).

The refresh control circuit 316 includes a refresh state control circuit 336 which receives the refresh signal REF from the interface 326, and determines how many normal and targeted refresh operations may be performed by issuing internal refresh signal IREF and/or targeted refresh signal RHR. The number (and/or type) of internal refresh signals IREF and RHR provided for each refresh signal REF may be based on refresh rate adjustment signals from a refresh rate adjustment circuit 342 (e.g., 132 of FIGS. 1 and/or 217 of FIG. 2). Responsive to IREF and/or RHR, a refresh address generator 338 of the refresh control circuit 316 provides a refresh address RXADD. The refresh control circuit 316 also includes an aggressor detector circuit 332 which determines if an accessed row address XADD is an aggressor or not, and a targeted refresh queue 340 which stores the identified aggressor addresses. When the refresh state control circuit 336 calls for a targeted refresh operation, the refresh address generator 338 generates the refresh address RXADD based on an aggressor address HitXADD from the queue 340.

The DRAM interface 326 represents various components of the memory which send and receive signals and addresses to the refresh control circuit 316 and row decoder 350. The signals may be based on commands and/or addresses received from outside the memory (e.g., from a controller such as 250 of FIG. 2) and/or may be internally generated signals. As part of access operations, the DRAM interface 326 provides a row address XADD along with an activation signal ACT. Responsive to the signal ACT, the row decoder activates the word line of the memory array 350 associated with XADD. At the end of the access operation, the DRAM interface provides a pre-charge command PRE, and responsive to that the active word line is pre-charged (e.g, deactivated or closed). As part of refresh operations, the DRAM interface provides a refresh signal REF, which may be based on a refresh command received from a controller (e.g., REF_CMD of FIG. 1). Responsive to the refresh signal REF, the refresh control circuit 316 performs one or more refresh operations. The number and/or type of refresh operation (e.g., the rate of refresh operations) may be set based, in part, on refresh rate adjustment signals provided by the refresh rate adjustment circuit 342.

The refresh state control circuit 336 may store a refresh rate for the memory device 300. The refresh rate may be set based on one or more factors, such as a measured temperature of the memory. The refresh rate may determine how many refresh ‘pumps’, for example activations of the signal IREF, are preformed responsive to REF. In other words, the refresh rate may determine how many refresh operations are performed each time REF is received. In some embodiments, the value of the refresh rate may be set at a baseline level based on settings of the device, internal signals (e.g., the temperature measurement) etc. The baseline refresh rate may change over time as these factors change. The refresh rate may be adjusted away from its baseline based on one or more refresh rate adjustment signals provided by the refresh rate adjustment circuit 342. In some embodiments, changes in the baseline refresh (e.g., due to temperature) may change when the refresh rate adjustment circuit 342 adjusts the baseline refresh up or down.

As shown in the example of FIG. 3, there are two refresh rate adjustment signals, and upwards adjustment signal RefRateUp and a downwards adjustment signal RefRateDown. In some embodiments, only one signal may be used. For example, the refresh rate signal may adjust the refresh rate upwards but not downwards. In some embodiments, those may be static signals. For example, when the signal RefRateUp is active, the refresh rate is adjusted one ‘step’ up (e.g., to increase refresh pumps per REF) from the baseline value. When the signal RefRateUp is not active, the baseline value may be used. In some embodiments, the refresh adjustment signals may be pulse signals and each pulse may adjust the refresh rate away from baseline by one ‘step’, and then a second pulse may increase the rate by another step. In some embodiments, the refresh adjustment signals may be multi-bit signals which instruct how many steps to adjust the refresh rate, what direction to adjust the refresh rate, or combinations thereof.

The refresh state control circuit 336 receives the refresh signal REF and generates one or more activations of an internal refresh signal IREF and/or a targeted refresh signal RHR. The number of times that IREF/RHR are activated, and in what combination, determines a sequence of refresh operations performed responsive to REF. In an example embodiment, if IREF is active, but not RHR, a normal refresh operation may be performed. If both IREF and RHR are active, then a targeted refresh operation may be performed.

The refresh state control circuit 336 may determine how many refresh operations to perform responsive to REF, and what distribution of normal and targeted refresh operations, based on the refresh rate. For example, responsive to REF, for a given refresh rate setting the refresh state control circuit may perform 3 refresh operations (e.g., three ‘pumps’ of the internal refresh signal IREF per REF). Two of those pumps may be targeted refresh operations and the third may be a normal refresh operation. If the refresh rate is adjusted upwards (e.g., by RefRateUp) then 4 refresh operations may be performed. If the refresh rate is adjusted downwards (e.g., by RefRateDown) then two refresh operations may be performed.

The refresh address generator circuit 338 provides a refresh address RXADD which indicates which word line or word lines should be refreshed as part of a refresh operation. As part of a normal refresh operation (e.g., when IREF but not RHR is active), sequence logic may be used to generate the refresh address. For example, the refresh address generator circuit 338 may include a counter circuit which generates a new normal refresh address based on a previous normal refresh address. Responsive to the refresh address RXADD and the refresh signal IREF, the row decoder 308 refreshes one or more word lines associated with the refresh address RXADD. In some embodiments, the normal refresh address may be associated with multiple word lines. For example, during a normal refresh operation the refresh address RXADD may be truncated, and all the word lines associated with that truncated portion may be refreshed in common.

As part of a targeted refresh operation (e.g., when both IREF and RHR are active), the refresh address generator 338 generates the refresh address RXADD based on an identified aggressor address HitXADD provided by the targeted refresh queue 340. The refresh address generator 338 may generate multiple refresh addresses based on a single aggressor address HitXADD. For example, the refresh address generator 338 may generate a first refresh address associated with a first word line adjacent to the word line associated with HitXADD and a second refresh address associated with a second word line adjacent to the word line associated with HitXADD. In some embodiments, other relationships may also be used. For example, every Nth targeted refresh operation, word lines further away than adjacent from the word line associated with HitXADD may be refreshed. In some embodiments, the refresh address RXADD generated as part of a targeted refresh operation may be associated with a single word line. Responsive to the refresh address RXADD and the refresh signal IREF, the word line associated with RXADD is refreshed by the row decoder 308. In some embodiments, the refresh address may be associated with fewer word lines during a targeted refresh operation than during a normal refresh operation. In other words, fewer word lines may be refreshed as part of a targeted refresh operation than a normal refresh operation.

The refresh control circuit 316 includes an aggressor detector circuit 332 which determines if a row address XADD should be added to the targeted refresh queue 340 or not (e.g., if the row address XADD is an aggressor address). When the current row address is determined to be an aggressor, the aggressor detector circuit provides an aggressor signal Agg. The aggressor detector circuit 332 may use various criteria to determine if the address is an aggressor. In some embodiments, random sampling may be used. In some embodiments, the aggressor detector circuit 332 may store addresses and count a number of times they are accessed. In some embodiments, an example of which is shown in FIG. 3 and described in more detail herein, per-row activity tracking (PRAC) may be used. However, the present disclosure is not limited to the use of PRAC for tracking aggressor addresses.

In embodiments where PRAC is used, the memory array 350 includes a number of a counter memory cells which store a number of count values XCount each associated with a word line of the memory. For example, each word line may include a set of counter memory cells which store that word lines count value XCount as a binary number. When a word line is accessed, its count value XCount is read out to the aggressor detector circuit 332. The aggressor detector circuit 332 updates the count value XCount (e.g., by incrementing it) and compares the updated count to a threshold. If the count has not crossed the threshold, then the updated count value is written back to the counter memory cells 352. If the count has crossed the threshold (e.g., is equal to or greater than the threshold) then the aggressor detector circuit 332 provides an aggressor signal Agg, and resets the count value (e.g., to an initial value such as 0). In some embodiments, the threshold may be a maximum value of the count, and the count may cross the threshold when it ‘rolls over’ from a maximum value back to the initial value.

The targeted refresh queue 340 includes a register with one or more slots, each of which may store an address. The queue 340 may be made from content addressable memory (CAM) cells, and may be referred to as a CAM in some embodiments. Responsive to the signal Agg, the targeted refresh queue 340 stores the current row address XADD in an empty one of the slots. Responsive to targeted refresh operation (e.g., the signal RHR), an address in the queue 340 is provided as HitXADD and removed from the queue 340.

The refresh control circuit 316 includes a refresh rate adjustment circuit 342. The refresh rate adjustment circuit 342 determines whether to adjust the refresh rate based on ECS information. The DRAM interface 326 includes an ECS logic circuit 328 which performs ECS operations over the course of an ECS cycle. Each ECS operation involves reading a codeword from a word line of a memory along with its parity out to the ECC circuit (e.g., 220 of FIG. 2). The ECC circuit determines if there is a correctable error in the codeword, and if so corrects it, adjusts the ECS information (e.g., by incrementing an ECS count), and writes the corrected codeword back to the array. The ECS logic 328 may perform ECS operations such that each codeword in the memory array 350 is checked over the course of an ECS cycle. The duration of the ECS cycle may be a setting of the memory device 300. For example, the ECS cycle may be 24 hours.

The ECS logic circuit 328 may record information about the errors detected during the ECS operations, for example by setting them as values in one or more ECS registers (e.g., 134 of FIGS. 1 and/or 232 of FIG. 2) of a mode register 329 (e.g., 230 of FIG. 2). In some embodiments, the ECS register may store an ECS count which counts a number of errors detected over the course of an ECS cycle. In some embodiments, the ECS register may store multiple ECS counts, for example a different count for each bank of the memory array. In some embodiments, the ECS register may be continuously updated over the course of the ECS cycle. In some embodiments, the ECS logic circuit 328 may keep track of the ECS value and only update the register at the end of the ECS cycle.

The ECS logic circuit 328 may provide a refresh adjustment timing signal RefAdj to indicate that the refresh rate adjustment circuit 342 should check the ECS information and provide rate adjustment signals. For example, the refresh adjustment timing signal RefAdj may be provided at the end of an ECS cycle in some embodiments. In some embodiments, the refresh adjustment timing signal RefAdj may be provided after ECS operations are performed on some sub-set of the memory array 350. For example, the signal RefAdj may be provided after ECS operations are performed on a bank or a portion thereof. In some embodiments, the ECS information may be continuously monitored, and the signal RefAdj may be provided each time ECS operations along a word line are completed.

The refresh rate adjustment circuit 342 may use the ECS information to determine whether or not to adjust the refresh rate, which direction to adjust the refresh rate, how much to adjust the refresh rate, or combinations thereof. The refresh rate adjustment circuit 342 may perform checks responsive to the signal RefAdj. In an example implementation, the refresh rate adjustment circuit 342 may store previous ECS information 343. For example, the previous ECS information 343 may represent the ECS information from a previous ECS cycle. In some embodiments, the current ECS information may be compared to the previous ECS information 343 to determine if the refresh rate should be adjusted. In some embodiments, the current ECS information may be used alone.

In an example implementation, at the end of an ECS cycle the refresh rate adjustment circuit 342 may receive an ECS count for the current ECS cycle (the one that just completed) and compare the ECS count to the ECS count from the previous ECS cycle. If the difference between the two counts is outside a tolerance, the refresh rate adjustment circuit 342 provides the refresh adjustment circuit. In some embodiments the tolerance may be set in absolute terms (e.g., a set range of values). In some embodiments, the tolerance may be set relative to the ECS count value (e.g., +/−10% of the ECS value). In a similar example embodiment, the ECS count for a given bank may be compared to the previous ECS count for that bank when ECS operations are done in that bank.

In an example implementation, the ECS information may be continuously monitored. For example, the refresh rate adjustment circuit may receive the ECS count value as well as information about the progress of ECS operations. The refresh rate adjustment circuit may track a rolling count of errors detected over the previous set of N word lines which had ECS operations performed along them. For example, if N is 10, then the rolling count of errors may represent the number of errors counted in codewords stored in any of the previous 10 word lines to have ECS operations performed along them. When the ECS operations move to a next word line, the rolling count may be adjusted to remove the errors associated with the oldest word line (which is now the 11^{th} previous word line and thus outside the window). If that rolling count rises above a threshold, the refresh rate may be increased.

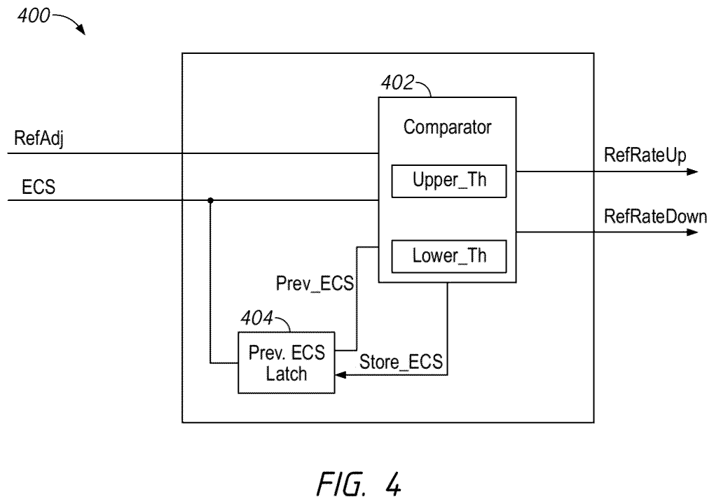

FIG. 4 is a block diagram of a refresh rate adjustment circuit according to some embodiments of the present disclosure. The refresh rate adjustment circuit 400 may, in some embodiments, implement the refresh rate adjustment circuit 132 of FIG. 1, 217 of FIG. 2, and/or 342 of FIG. 3.

The refresh adjustment circuit 400 includes a comparator circuit 402 and a latch circuit 404. The latch circuit 404 stores one or more previous ECS values Prev_ECS. The comparator circuit 402 receives current ECS information ECS (e.g., from register 134 of FIG. 1, 232 of FIG. 2, and/or 329 of FIG. 3) and compares the current ECS information to the previous ECS information Prev_ECS stored in the latch 404. Based on that comparison the comparator circuit 402 provides refresh adjustment signals. In the example implementation of FIG. 4, the comparator provides an upwards adjustment signal RefRateUp and a downwards adjustment signal RefRateDown. However, other signals and patterns of signals may be used in other example embodiments.

Responsive to the signal RefAdj, the comparator circuit 402 compares the current ECS information to the previous ECS information Prev_ECS stored in the latch circuit 404. The comparator circuit 402 compares the current and previous ECS information to determine how to adjust the refresh rate. For example, the comparator circuit 402 may take a difference between the current ECS information and the previous ECS information Prev_ECS and use the difference to determine how to adjust the refresh rate. A positive difference (e.g. ECS>Prev_ECS) may indicate the number of errors is increasing. A negative difference (e.g., ECS<Prev_ECS) may indicate the number of errors is decreasing. In some embodiments, the difference may be compared to one or more thresholds. In some embodiments, the thresholds may have a fixed value. In some embodiments, the thresholds may have a value based on the value of the current ECS information, previous ECS information, or combinations thereof. For example, the thresholds may be set as some percentage of the previous ECS information.

In the example of FIG. 4, two thresholds are shown, an upper threshold Upper_Th and a lower threshold Lower_Th. The upper threshold Upper_Th may represent an upper tolerance, or an amount of increase in the number of errors represented by the ECS information which is acceptable, while the lower tolerance Lower_Th represents a lower tolerance, or an amount of decrease in the number of errors represented by the ECS information which is acceptable. For example, if the difference between ECS and Prev_ECS is a positive value which is larger than Upper_Th (e.g., the number of errors has increased by more than Upper_Th), then the comparator may increase the refresh rate, for example by providing RefRateUp. If the difference between ECS and Prev_ECS is a negative number which is less than Lower_Th (e.g., the number of errors is less by more than Lower_Th) then the comparator 402 may decrease the refresh rate, for example by providing RefRateDown. If the difference is between Upper_Th and Lower_Th, then the comparator 402 may take no action (e.g., by providing neither RefRateUp nor RefRateDown).

After performing the comparison, the comparator 402 may provide an ECS storage signal Store_ECS. Responsive to the signal Store_ECS, the latch 404 stores the current value of ECS in the latch 404 as the new previous value Prev_ECS.

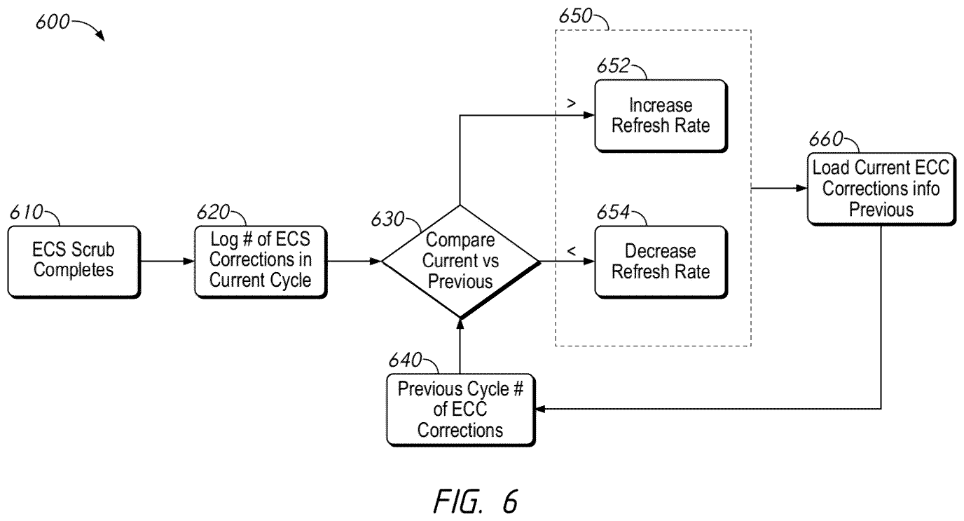

In an example implementation, the signal RefAdj may be provided at the end of an ECS cycle, accordingly, the current ECS information may represent the number of errors counted over the course of the ECS cycle which just ended, while the previous ECS information stored in the latch may represent the number of errors counted over the course of the ECS cycle prior to that. The upper and lower thresholds may be set as a percentage of the previous ECS value Prev_ECS. For example the upper threshold Upper_Th may be set as +M % of Prev_ECS while the lower threshold Lower_Th may be set as −M % of Prev_ECS. An example operation using whole ECS cycle counting is described in more detail in FIG. 6.

Other levels of granularity may also be used. For example, if the signal RefAdj is provided after performing ECS operations on some subset of the memory array (e.g., per bank) then the ECS information ECS may represent a count of errors detected in that portion, and the latch circuit 404 may store multiple previous ECS values, one for each portion. The appropriate previous value may be retrieved, compared, and overwritten. For example, the refresh adjustment circuit 400 may receive a signal which indicates an index of which portion's ECS operations were just completed (e.g., which bank). Accordingly, responsive to Store_ECS the latch may store the signal ECS in the latch associated by the index.

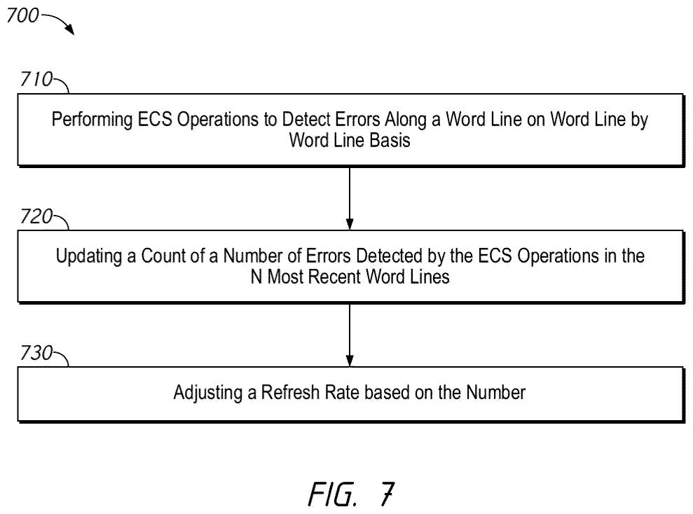

In another example implementation, continuous monitoring of the ECS signal may be used. In such an embodiment, the refresh adjustment circuit 400 may count a total value of errors detected during ECS operations on the previous N word lines. The count value ECS may be stored in a register of the latch circuit 404. The signal RefAdj may indicate that ECS operations were completed along a word line and responsive to RefAdj, the register of the latch 404 may be changed. In this way, each register may store the number of errors along a word line, and may be updated continuously on a word line-by-word line basis. The latch 404 may have N registers, each of which stores a count along a word line. The latch 404 may function as a FIFO queue, and when full, the newest entry may bump the oldest entry out of the queue. Accordingly, the latch 404 may store the previous N word lines worth of ECS counts. The comparator circuit 402 sums the values in the registers of the latch 404 to determine a count of errors detected along the previous N word lines. That sum is compared to a threshold. If the count rises above the threshold, the signal RefRateUp may be provided until the count falls below the threshold again. An example method of continuously monitoring ECS information is described in more detail in FIG. 7.

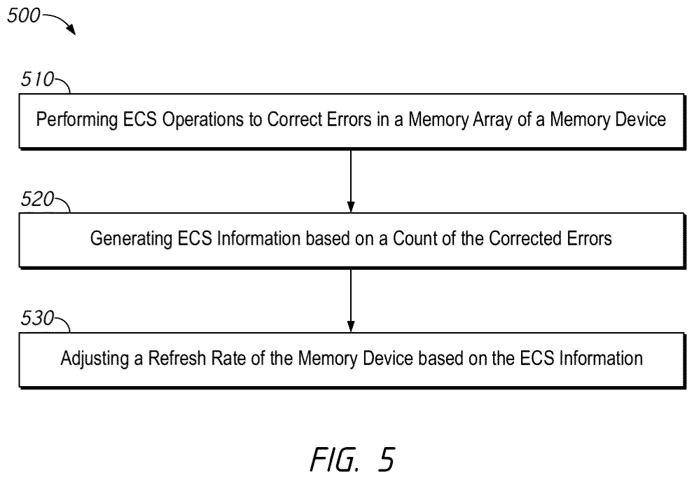

FIG. 5 is a flow chart of a method of adjusting refresh rates based on ECS information according to some embodiments of the present disclosure. The method 500 may, in some embodiments, be implemented by one or more of the apparatuses and/or systems described herein. For example, the method 500 may be implemented by the memory devices 104/110 of FIG. 1, 200 of FIG. 2, and/or 300 of FIG. 3 using refresh rate adjustment circuits such as 132 of FIG. 1, 217 of FIG. 2, 342 of FIG. 3, and/or 400 of FIG. 4.

The method 500 begins with box 510 which describes performing ECS operations to correct errors in a memory array of a memory device. For example, an ECS logic circuit (e.g., 328 of FIG. 3) may generate a row and column address and provide them to their respective decoders. The codeword specified by the row and column address along with its parity is read out to the ECC circuit (e.g., 220 of FIG. 2) which determines if there is an error in the codeword and if so, corrects it. The corrected codeword is written back to the same location. If the codeword was not the final one along the word line (e.g., the column address did not have the maximum value), then during the next ECS operation the same row is accessed but a next column address is provided. If the final codeword is reached, the row address updates to a next value, and the column address resets to a first value. If the final row address is reached, it indicates the end of an ECS cycle.

Box 510 is followed by box 520, which describes generating ECS information based on a count of the corrected errors. For example, when an error is detected as part of an ECS operation a signal is provided to the ECS logic, which updates ECS information. For example, the method may include counting a number of errors detected by incrementing an ECS count value each time an error is detected.

Box 520 is followed by box 530, which describes adjusting a refresh rate of the memory device based on the ECS information. For example, the ECS information may be compared to one or more thresholds. In some embodiments, the method 500 may include comparing the ECS information to previous ECS information and adjusting the refresh rate based on the comparison. For example a change between current and previous ECS information may be compared to one or more thresholds. In some embodiments, the ECS information may be continuously monitored over time. For example, the method 500 may include counting a number of errors detected by the ECS operations over a previous N word lines, and comparing the count to a threshold.

The method 500 may include adjusting the refresh rate by changing a quantity of refresh operations performed responsive to a refresh command (e.g., REF_CMD of FIG. 1). For example, the method 500 may include performing a quantity of refresh operations based on a refresh rate value and changing the refresh rate value based on the ECS information.

The method 500 may include increasing the refresh rate if the ECS information indicates an increased number of errors. In some embodiments, the method 500 may also include decreasing the refresh rate if the ECS information indicates a decreased number of errors. In some embodiments, the method may include keeping the refresh rate the same if the ECS information indicates that a change in the number of errors is within a tolerance.

FIG. 6 is a flow chart of a method of adjusting refresh rates based on ECS information at the end of an ECS cycle according to some embodiments of the present disclosure. The method 600 may, in some embodiments, be implemented by one or more of the apparatuses and/or systems described herein. For example, the method 600 may be implemented by the memory devices 104/110 of FIG. 1, 200 of FIG. 2, and/or 300 of FIG. 3 using refresh rate adjustment circuits such as 132 of FIG. 1, 217 of FIG. 2, 342 of FIG. 3, and/or 400 of FIG. 4. The method 600 may be an implementation of the method 500 of FIG. 5. For the sake of brevity, certain details already described with respect to FIG. 5 will not be repeated again for the sake of FIG. 6.

The method 600 includes block 610, which describes completing an ECS cycle. For example, the method 600 may include performing ECS operations on each of the codewords in the memory array as part of the ECS cycle. The ECS cycles may repeat.

Block 610 is followed by block 620, which describes determining a number of errors which were corrected over the course of the ECS cycle. For example, the ECS logic circuit may include a counter circuit which increments an ECS count value each time an error is corrected in a codeword. At the end of the ECS cycle, that value may be written to an ECS register and/or provided to the refresh rate adjustment circuit as the ECS information. When a next ECS cycle begins, the counter circuit resets the ECS count value.

Block 620 is followed by block 630, which describes comparing current and previous ECS information. The current information is generated over the course of an ECS as represented by the steps of blocks 610 and 620 and represents a count of errors corrected over the just completed ECS cycle. The previous ECS information represents the ECS information from the ECS cycle before that. In some embodiments, each ECS cycle may be completed over the course of 24 hours. In some embodiments, since the method 600 involves comparing current and previous ECS information, the adjustment of the refresh rate may not be performed until at least two ECS cycles have completed. For example, after the device is initialized (or rebooted, etc.) at the end of the first ECS cycle (e.g., after boxes 610 and 620), the boxes 630-650 maybe skipped, and the instead the initial ECS information may be stored as the previous ECS information (e.g., box 660). The full method may then be performed at the end of a next ECS cycle. The comparing 630 may include taking a difference between the current ECS information and the previous ECS information.

Box 630 is followed by box 650, which describes adjusting the refresh rate based on the comparison between the current and previous ECS information. Box 650 includes box 652 which describes increasing the refresh rate if the ECS count increased from the previous ECS cycle to the current ECS cycle. Box 650 also includes box 654, which describes decreasing the refresh rate if the ECS count decreased from the previous ECS cycle to the current ECS cycle.

In some embodiments, change between the previous and current ECS counts may be compared to one or more thresholds, such as an upper and lower threshold. Box 652 may include increasing the refresh rate if the change between the current and previous ECS information is greater than an upper threshold while box 654 may include decreasing the refresh rate if the change between the current and previous ECS information is below a lower threshold. The method 600 may include keeping the refresh rate at its current level if the change between the current and previous ECS information is between the upper and lower threshold. In some embodiments, the method 600 may include setting a value of the upper and lower thresholds based on the previous ECS information. For example the method may include determining the upper and lower threshold as a percentage of the previous ECS information. In some embodiments the upper and lower threshold may represent the same percentage (e.g., +/−M % of the previous ECS information). In some embodiments, the upper and lower thresholds may represent different percentages (e.g., +i % and −j %).

Box 650 is followed by box 660, which describes loading the current ECS information into a latch as the previous ECS information. Box 660 is followed by box 640, which describes storing the previous ECS information (e.g., in latch 404 of FIG. 4).

In some embodiments, the method 600 may be performed when ECS operations on performed on a portion of the memory array rather than waiting for the entire ECS cycle to finish. For example, each bank may have its own ECS counter and the method 600 may be repeated for each bank.

FIG. 7 is a flow chart of a method of continuously monitoring ECS information and adjusting the refresh rate based on that monitoring according to some embodiments of the present disclosure. The method 700 may, in some embodiments, be implemented by one or more of the apparatuses and/or systems described herein. For example, the method 700 may be implemented by the memory devices 104/110 of FIG. 1, 200 of FIG. 2, and/or 300 of FIG. 3 using refresh rate adjustment circuits such as 132 of FIG. 1, 217 of FIG. 2, 342 of FIG. 3, and/or 400 of FIG. 4. The method 700 may be an implementation of the method 500 of FIG. 5. For the sake of brevity, certain details already described with respect to FIG. 5 will not be repeated again for the sake of FIG. 7.

The method 700 begins with box 710, which describes performing ECS operations to detect errors in codewords along a word line on a word line-by-word line basis. For example, box 710 may include performing an ECS operation on each codeword along a word line and then moving on to a next word line to perform ECS operations on the codewords stored along that word line and so forth.

Box 710 is followed by box 720, which describes updating a count of a number of errors detected by the ECS operations along the N most recent word lines. For example, the method may include updating a count value each time an error is detected/corrected along a word line. The method 700 may include updating the count value in a register and moving to a different slot of the register when the ECS operations complete along a current word line. The method 700 may include storing up to N previous count values in the slots of the register. Box 720 may include summing the count values in the register to find the current count of errors detected along the N most recent word lines to be checked by ECS operations.

Box 720 is followed by box 730, which describes adjusting a refresh rate based on the number. For example, if the number rises above a threshold, the refresh rate may be increased. In some embodiments the refresh rate may be increased for a period of time. In some embodiments, the refresh rate may remain increased until the count falls below the threshold.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array;
an error check and scrub (ECS) logic circuit configured to generate ECS information based on a count of errors in the memory array; and
a refresh control circuit configured to perform one or more of refresh operations responsive to a refresh signal, wherein a quantity of the one or more refresh operations is determined based on the ECS information.

2. The apparatus of claim 1, wherein the ECS logic circuit is configured to update the ECS information at the end of an ECS cycle, and
wherein the refresh control circuit is configured to compare the updated ECS information to previous ECS information and determine the quantity of the one or more refresh operations based on the comparison.

3. The apparatus of claim 2, wherein the refresh control circuit is configured to compare a difference between the updated ECS information and the previous ECS information to an upper threshold and to a lower threshold, wherein the refresh control circuit is configured to determine the quantity based on the comparison.

4. The apparatus of claim 2, wherein the refresh control circuit includes a refresh rate adjustment circuit comprising:
a latch configured to store the previous ECS information;
a comparator circuit configured to determine a difference between the updated ECS information and the previous ECS information, wherein the comparator is configured to provide a refresh rate adjustment signal based on the difference and wherein the number is adjusted based on the refresh rate adjustment signal.

5. The apparatus of claim 1, wherein the ECS logic circuit is configured to update a selected one of a plurality of ECS information values, each associated with a bank of the memory array, after performing a set of ECS operations on the respective bank, and
wherein the refresh rate control circuit is configured to determine the quantity of the one or more refresh operations based on one of the plurality of ECS information values when the ECS information is updated.

6. The apparatus of claim 1, wherein the refresh rate control circuit is configured to continuously monitor the ECS information as it is updated.

7. The apparatus of claim 6, wherein the memory array includes a plurality of word lines,
wherein the ECS logic circuit configured to perform ECS operations on a word line by word line basis, and
wherein the refresh rate control circuit is configured to determine an error rate based on the number of errors detected on the previous N word lines.

8. The apparatus of claim 1, wherein the refresh control circuit includes a baseline refresh rate which determines a base line quantity of refresh operations, and
wherein the quantity is adjusted away from the base line number based on the ECS information.

9. The apparatus of claim 1, further comprising an error correction code (ECC) circuit configured to correct errors in a codeword,
wherein the ECS information includes an ECS count, and
wherein the ECS logic circuit is configured to cause a codeword to be read out to the ECC circuit, and wherein the ECS logic circuit is further configured to increment the ECS count responsive to the ECC circuit correcting an error in the codeword.

10. An apparatus comprising:
a module logic circuit configured to provide a refresh command;
a plurality of memory devices configured to receive the refresh command in common, each of the plurality of memory devices comprising:
a register configured to store error correct and scrub (ECS) information;
a refresh rate adjustment circuit configured to determine a quantity of refresh operations performed by the memory device responsive to the refresh command based on the ECS information.

11. The apparatus of claim 10, wherein a first and a second of the plurality of memory devices perform different numbers of refresh operations responsive to the same refresh command.

12. The apparatus of claim 10, wherein each of the plurality of memory devices further includes:
a memory array configured to store a plurality of codewords;
an error correct code (ECC) circuit configured to correct errors in a codeword as part of an ECS operation;
an ECS logic circuit configured to perform ECS operations on each of the plurality of codewords and update the ECS information if an error was detected by the ECC circuit.

13. A method comprising:
performing error correct and scrub (ECS) operations to correct errors in a memory array of a memory device;
generating ECS information based on a count of the corrected errors; and
adjusting a refresh rate of the memory device based on the ECS information.

14. The method of claim 13, further comprising:
updating the ECS information at the end of an ECS cycle;
comparing the updated ECS information to previous ECS information from a previous ECS cycle; and
adjusting the refresh rate based on the comparing.

15. The method of claim 14, further comprising:
finding a difference between the updated ECS information and the previous ECS information and adjusting the refresh rate based on the difference.

16. The method of claim 14, further comprising:
comparing the difference to an upper threshold and increasing the refresh rate if the difference is above the upper threshold;
comparing the difference to a lower threshold and decreasing the refresh rate if the difference is below the lower threshold; and
keeping the refresh rate at a current level if the difference is between the upper threshold and the lower threshold.

17. The method of claim 13, further comprising continuously monitoring the ECS information during ECS operations.

18. The method of claim 17, further comprising:
performing ECS operations to detect errors along a word line on a word line-by-word line basis;
updating a count of a number of errors detected by the ECS operations in the N most recent word lines; and
adjusting the refresh rate based on the number of errors in the N most recent word lines.

19. The method of claim 13, further comprising performing the ECS operation by:
reading a codeword from the memory array to an error correction code (ECC) circuit;
correcting an error in the codeword with the ECC circuit;
writing the corrected codeword back into the memory array; and
updating the ECS information if an error was corrected.

20. The method of claim 13, further comprising adjusting the refresh rate by changing a quantity of refresh operations performed responsive to a refresh command.
